(19) United States
(12) Patent Application Publication
(10) Pub. No.: US 2025/0029963 A1
(43) Pub. Date: Jan. 23, 2025

(54) DISPLAY APPARATUS AND ARRAY SUBSTRATE

(71) Applicant: AUO Corporation, Hsinchu (TW)

(72) Inventors: Yu-Lun Chang, Hsinchu (TW); Kuan-Hsun Chen, Hsinchu (TW)

(73) Assignee: AUO Corporation, Hsinchu (TW)

(21) Appl. No.: 18/768,005

(22) Filed: Jul. 10, 2024

(30) Foreign Application Priority Data
Jul. 19, 2023 (TW) 112126883

(51) Int. Cl. H01L 25/075; H01L 27/12; H01L 33/54; H01L 33/56

(52) U.S. Cl. CPC H01L 25/0753; H01L 27/124; H01L 33/54; H01L 33/56

(57) ABSTRACT

A display apparatus includes a circuit substrate, light-emitting elements, a bonding pad and an encapsulation glue layer. The circuit substrate has a display area, an outer lead bonding area and a connection area connected between the display area and the outer lead bonding area. The light emitting elements are disposed on the display area of the circuit substrate. The bonding pad is disposed on the outer lead bonding area of the circuit substrate. The encapsulation glue layer is disposed on the circuit substrate and includes a flat portion and a thick wall portion connected with each other. The flat portion covers the light emitting elements. The thick wall portion extends to the connection area. The thick wall portion has a thickness which gradually increases toward the outer lead bonding area. In addition, an array substrate is also provided.

### CROSS-REFERENCE TO RELATED APPLICATION

This application claims the priority benefit of Taiwan application serial no. 112126883, filed on Jul. 19, 2023. The entirety of the above-mentioned patent application is hereby incorporated by reference herein and made a part of this specification.

### BACKGROUND

### Technical Field

The disclosure relates to a display apparatus and an array substrate.

### Description of Related Art

A light-emitting diode display panel includes a circuit substrate and a plurality of light-emitting diode elements transferred onto the circuit substrate. Inheriting the characteristics of light-emitting diodes, the light-emitting diode display panel has advantages of power saving, high efficiency, high brightness, and fast response time. In addition, compared with an organic light-emitting diode display panel, the light-emitting diode display panel further has advantages of easy color adjustment, long light emission life, no image burn-in, etc. Therefore, the light-emitting diode display panel is considered as a display technology of the next generation.

Generally speaking, in order to protect the light-emitting diode elements, the plurality of light-emitting diode elements are covered with an encapsulation glue layer. However, when the encapsulation glue layer covers the light-emitting diode elements, it also covers bonding pads on an outer lead bonding area, causing inconvenience in subsequent bonding of the bonding pads with a driving circuit board.

### SUMMARY

The invention provides a display apparatus that is easy to manufacture.

The invention provides an array substrate that is easy to manufacture.

The display apparatus of the present invention includes a circuit substrate, light emitting elements, a bonding pad and an encapsulation glue layer. The circuit board has a display area, an outer lead bonding area, and a connection area connected between the display area and the outer lead bonding area. The light emitting elements are disposed on the display area of the circuit substrate. The bonding pad is disposed on the outer lead bonding area of the circuit substrate. The encapsulation glue layer is disposed on the circuit substrate and includes a flat portion and a thick wall portion connected to each other. The flat portion covers the light emitting elements. The thick wall portion extends to the connection area. The thick wall portion has a thickness gradually increasing toward the outer lead bonding area.

In an embodiment of the invention, the display apparatus further includes an optical film disposed on the flat portion of the encapsulation glue layer and covers the light-emitting elements, wherein the thick wall portion of the encapsulation glue layer protrudes from the optical film.

In an embodiment of the invention, the thick wall portion has a first end and a second end opposite to each other, the first end of the thick wall portion is connected to the flat portion, the second end of the thick wall portion is located between the first end of the thick wall portion and the outer lead bonding area, an thickness of the second end of the thick wall portion is greater than an thickness of the first end of the thick wall portion, and a difference between the thickness of the second end of the thick wall portion and the thickness of the first end of the thick wall portion is less than or equal to 100 μm.

In an embodiment of the invention, the thick wall portion has a first end and a second end opposite to each other. The first end of the thick wall portion is connected to the flat portion, the second end of the thick wall portion is located between the first end of the thick wall portion and the outer lead bonding area, and a horizontal distance between the first end of the thick wall portion and the second end of the thick wall portion is less than or equal to 1000 μm.

In an embodiment of the invention, the display apparatus further includes an outer frame, wherein the outer frame defines an accommodation space, the accommodation space accommodates the bonding pad, the outer lead bonding area of the circuit substrate, the connection area of the circuit substrate, and the thick wall portion of the encapsulation glue layer, and the light-emitting elements are located outside the accommodation space.

In an embodiment of the invention, the display apparatus further includes a driving circuit board and a protective glue, wherein the driving circuit board is electrically connected to the bonding pad, a thick wall portion side surface of the thick wall portion of the encapsulation glue layer faces the bonding pad, the protective glue covers a connection between the driving circuit board and the bonding pad and extends to the thick wall portion side surface of the thick wall portion of the encapsulation glue layer.

In an embodiment of the invention, a height of the thick wall portion side surface of the thick wall portion is greater than a thickness of the protective glue.

In an embodiment of the invention, the encapsulation glue layer has an encapsulation glue layer side surface and a thick wall portion side surface connected to each other, the circuit substrate has a circuit substrate side surface and an outer lead bonding area side surface connected to each other, the thick wall portion side surface of the encapsulation glue layer faces the bonding pad, the outer lead bonding area side surface of the circuit substrate is far away from the display area of the circuit substrate and is a boundary of the outer lead bonding area of the circuit substrate, the encapsulation glue layer side surface of the encapsulation glue layer is substantially aligned with the circuit substrate side surface of the circuit substrate, and a horizontal distance between the thick wall portion side surface of the encapsulation glue layer and the outer lead bonding area side surface of the circuit substrate is greater than 0.

In an embodiment of the invention, the display apparatus further includes an optical film, which is disposed on a flat portion of the encapsulation glue layer and covers the light-emitting elements, wherein the optical film has an optical film side surface and an edge side surface connected to each other, an optical film side surface of the optical film, the encapsulation glue layer side surface of the encapsulation glue layer and the circuit substrate side surface of the circuit substrate are substantially aligned, and the thick wall portion side surface of the encapsulation glue layer is located between the edge side surface of the optical film and the outer lead bonding area side surface of the circuit substrate.

The array substrate of the present invention includes display units arranged in an array. Each of the display units includes a block of a circuit substrate, light-emitting elements and a bonding pad. The block of the circuit substrate has a display area, an outer lead bonding area, and a connection area connected between the display area and the outer lead bonding area. The light-emitting elements are disposed on the display area. The bonding pad is disposed on the outer lead bonding area.

In an embodiment of the invention, the array substrate further includes a protective layer covering outer lead bonding areas of the display units and staggered with display areas and connection areas of the display units.

In an embodiment of the invention, the display area, the connection area and the outer lead bonding area of each of the display units are arranged in a first direction, the display units are arranged in display unit rows, and display units of each of the display unit rows are arranged in a second direction, the first direction and the second direction are staggered, the protective layer includes protection pattern groups, and each of the protection pattern groups covers outer lead bonding areas of the display units of a corresponding display unit row along the second direction.

In an embodiment of the invention, each of the protection pattern groups includes at least one protection pattern. The array substrate further includes an encapsulation glue layer covering the protective layer, the display areas of the display units, the connection areas of the display units, and bonding pads of the display units, wherein the at least one protection pattern of each of the protection pattern group has end portions extending outside the encapsulation glue layer.

In an embodiment of the invention, each of the protection pattern groups includes a protection pattern extending continuously in the second direction and has end portions located on opposite sides of a corresponding display unit row.

In an embodiment of the invention, the encapsulation glue layer includes encapsulation patterns separated from each other, and the encapsulation patterns respectively cover the display units of a corresponding display unit row and cover the protection pattern.

In an embodiment of the invention, the encapsulation glue layer includes an encapsulation pattern, the encapsulation pattern continuously extends in the second direction and covers the display units of a corresponding display unit row and the protection pattern.

In an embodiment of the invention, a length of the protection pattern in the second direction is greater than the length of the encapsulation pattern in the second direction.

In an embodiment of the invention, the at least one protection pattern of each of the protection pattern groups includes protection patterns separated from each other, the protection patterns are arranged in the second direction, each of the protection patterns covers the outer lead bonding area of a display unit of the corresponding display unit row and has sub end portions respectively located on opposite sides of the display unit, and the end portions of the at least one protection pattern of each of protection pattern groups extending outside the encapsulation glue layer includes the sub end portions.

In an embodiment of the invention, the encapsulation glue layer includes encapsulation patterns separated from each other, and the encapsulation patterns respectively cover the display units of the corresponding display unit row and respectively cover the protection patterns.

In an embodiment of the invention, a length of the protection pattern in the second direction is greater than a length of a corresponding encapsulation pattern in the second direction.

### BRIEF DESCRIPTION OF THE DRAWINGS

FIG. 1A to FIG. 1E are schematic cross-sectional views of the manufacturing process of

a display apparatus according to an embodiment of the present invention.

FIG. 2A to FIG. 2D are schematic top views of the manufacturing process of part of the display apparatus according to an embodiment of the present invention.

FIG. 3A is a schematic cross-sectional view of an array substrate according to an embodiment of the invention.

FIG. 3B is a schematic top view of an array substrate according to an embodiment of the present invention.

FIG. 4A is a schematic cross-sectional view of an array substrate according to another embodiment of the present invention.

FIG. 4B is a schematic top view of an array substrate according to another embodiment

of the present invention.

FIG. 5A is a schematic cross-sectional view of an array substrate according to yet another embodiment of the present invention.

FIG. 5B is a schematic top view of an array substrate according to yet another embodiment of the present invention.

### DESCRIPTION OF THE EMBODIMENTS

Reference will now be made in detail to exemplary embodiments provided in the disclosure, examples of which are illustrated in accompanying drawings. Wherever possible, identical reference numerals are used in the drawings and descriptions to refer to identical or similar parts.

It should be understood that when a device such as a layer, film, region or substrate is referred to as being “on” or “connected to” another device, it may be directly on or connected to another device, or intervening devices may also be present. In contrast, when a device is referred to as being “directly on” or “directly connected to” another device, there are no intervening devices present. As used herein, the term “connected” may refer to physical connection and/or electrical connection. Besides, if two devices are “electrically connected” or “coupled”, it is possible that other devices are present between these two devices.

The term “about,” “approximately,” or “substantially” as used herein is inclusive of the stated value and a mean within an acceptable range of deviation for the particular value as determined by people having ordinary skill in the art, considering the measurement in question and the error associated with measurement of the particular quantity (i.e., the limitations of the measurement system). For example, “about” may mean within one or more standard deviations, for example, ±30%, ±20%, ±10%, or ±5% of the stated value. Moreover, a relatively acceptable range of deviation or standard deviation may be chosen for the term “about,” “approximately,” or “substantially” as used herein based on optical properties, etching properties or other properties, instead of applying one standard deviation across all the properties.

Unless otherwise defined, all terms (including technical and scientific terms) used herein have the same meaning as commonly understood by people of ordinary skill in the art. It will be further understood that terms, such as those defined in the commonly used dictionaries, should be interpreted as having a meaning that is consistent with their meaning in the context of the relevant art and the invention and will not be interpreted in an idealized or overly formal sense unless expressly so defined herein.

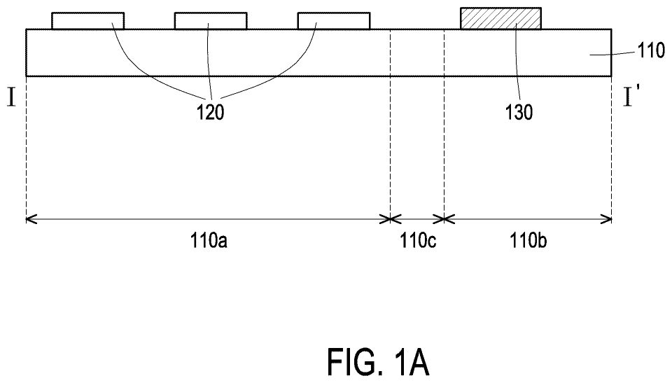

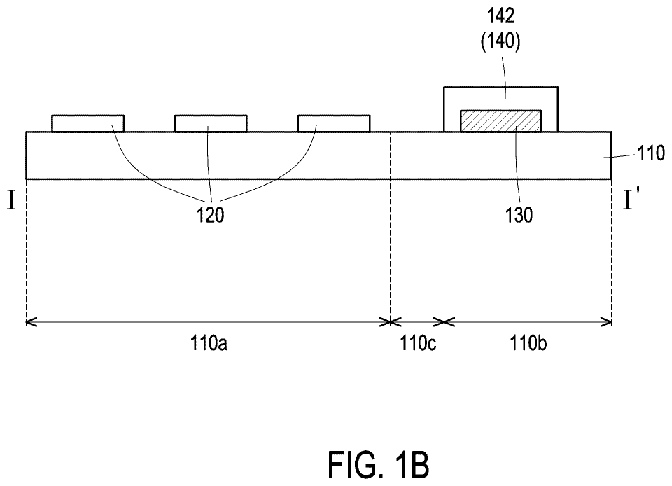

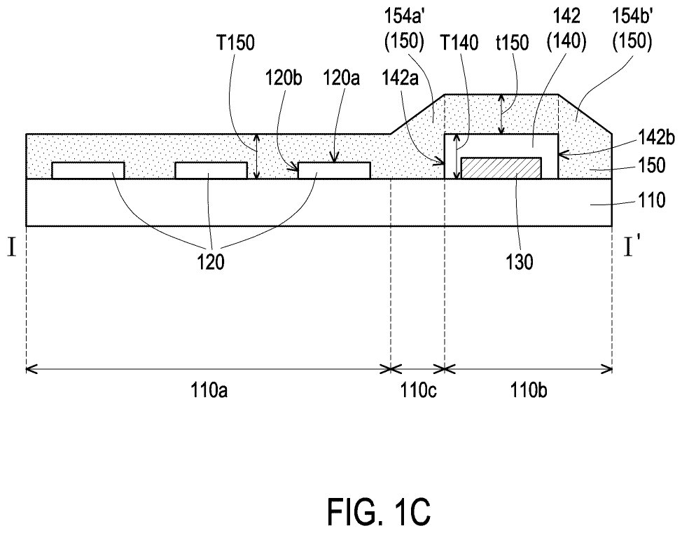

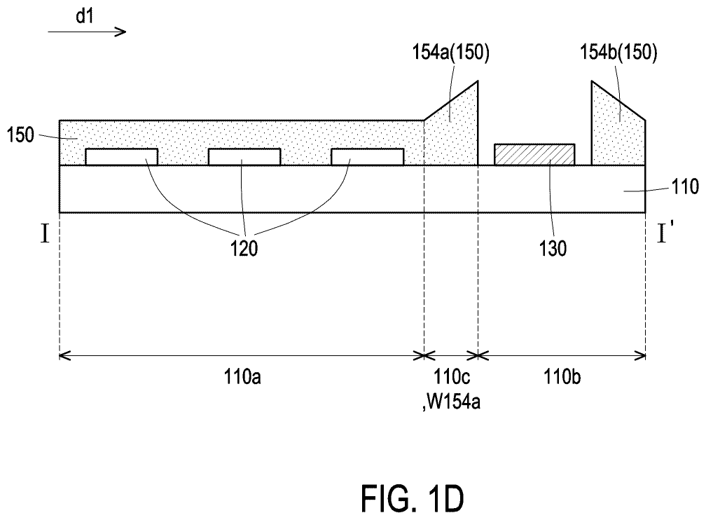

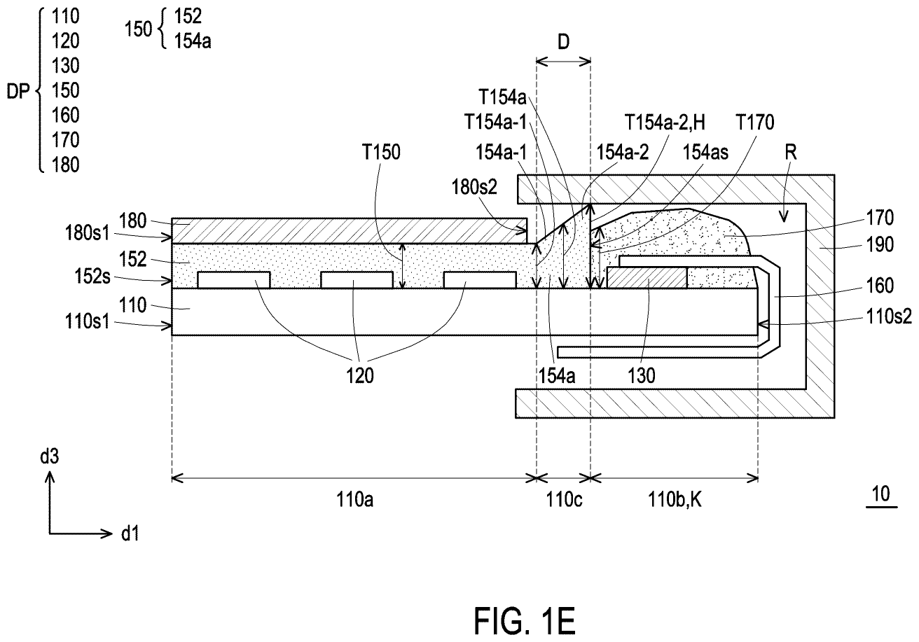

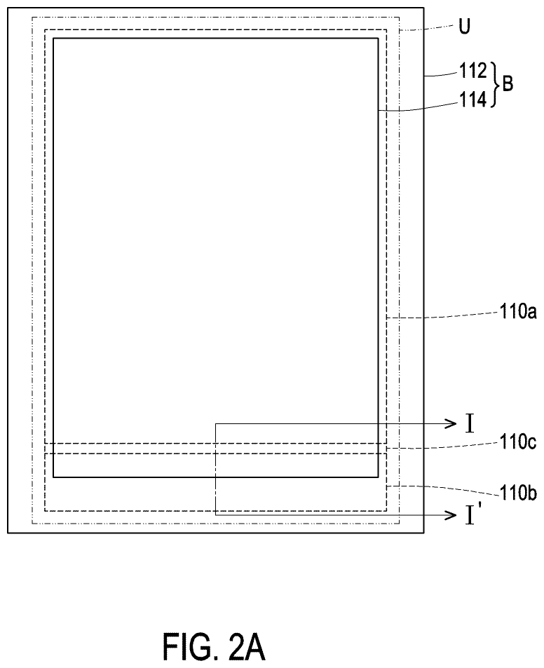

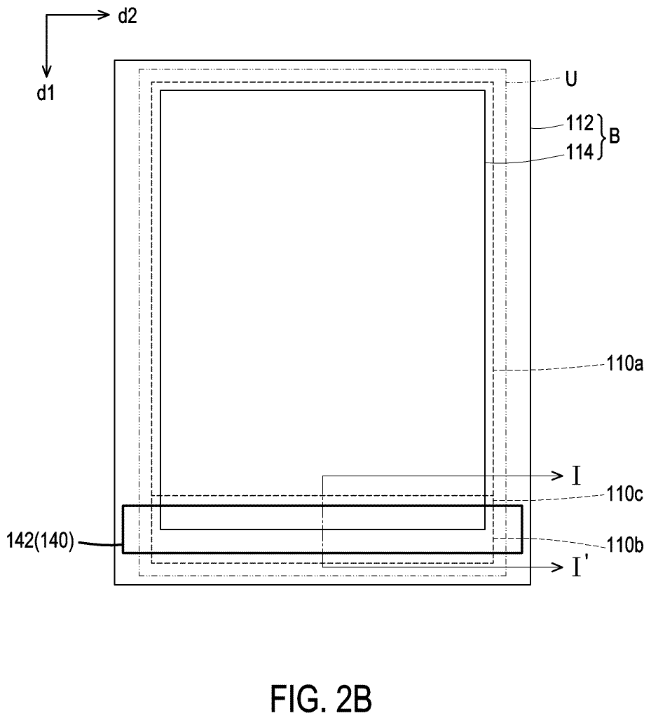

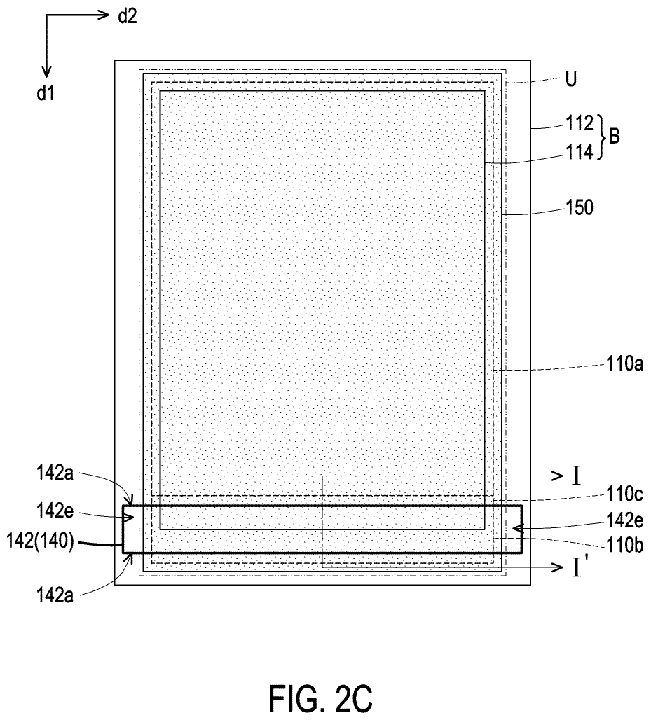

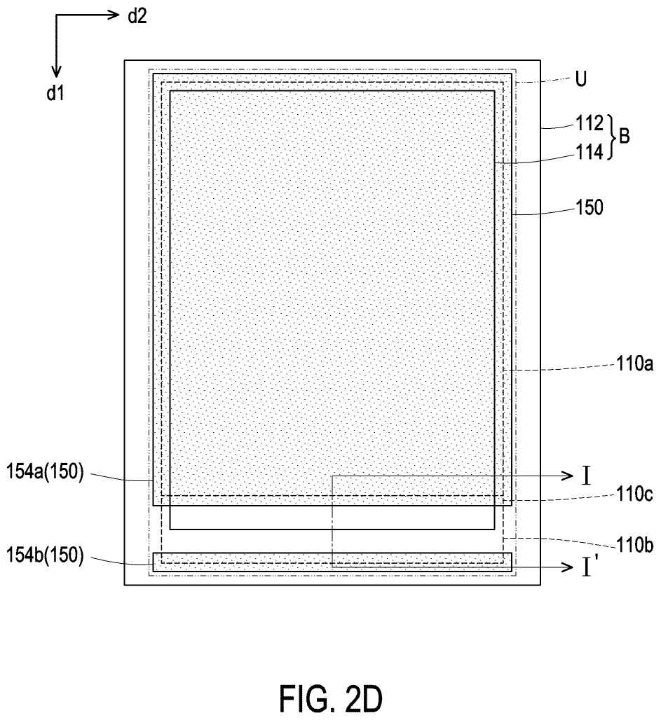

FIG. 1A to FIG. 1E are schematic cross-sectional views of the manufacturing process of a display apparatus according to an embodiment of the present invention. FIG. 2A to FIG. 2D are schematic top views of the manufacturing process of part of the display apparatus according to an embodiment of the present invention. FIG. 1A to FIG. 1D correspond to the cross-section line I-I′ of FIG. 2A to FIG. 2D respectively. FIG. 2A to FIG. 2D omit the light emitting element 120 and the bonding pad 130 of FIG. 1A to FIG. 1D.

Please refer to FIG. 1A and FIG. 2A. First, a circuit substrate 110, light emitting elements 120 and bonding pads 130 are provided. The circuit substrate 110 includes a base 112 and at least one driving circuit structure 114 disposed on the base 112. The circuit substrate 110 includes at least one block B. Each of the blocks B includes at least a portion of the base 112 and a driving circuit structure 114. Each of the blocks B has a display area 110a, an outer lead bonding area 110b, and a connection area 110c connected between the display area 110a and the outer lead bonding area 110b.

The light-emitting elements 120 are provided on the display area 110a of each of the blocks B of the circuit substrate 110. The light-emitting elements 120 are electrically connected to the driving circuit structure 114 of the block B. The bonding pads 130 are disposed on the outer lead bonding area 110b of each of the blocks B of the circuit substrate 110. The bonding pads 130 are electrically connected to the driving circuit structure 114 of the block B. Each of the display unit U may include a block B of the circuit substrate 110, light-emitting elements 120 disposed on the display area 110a of the block B, and bonding pads 130 disposed on the outer lead bonding area 110b of the block B. In one embodiment, the light-emitting elements 120 is, for example, a micro light-emitting diodes (μLED), but the invention is not limited thereto.

Specifically, in one embodiment, the driving circuit structure 114 of a block B of each display unit U may include pixel driving circuits (not shown) and signal lines electrically connected to the pixel driving circuits. Lines (not shown), the light-emitting elements 120 are electrically connected to the of pixel driving circuits, and the bonding pads 130 are electrically connected to the signal lines. For example, in one embodiment, each of the pixel driving circuit may include a first transistor (not shown), a second transistor (not shown) and a capacitor (not shown), wherein a second terminal of the first transistor is electrically connected to a control terminal of the second transistor, the signal lines may include data lines (not shown), scan lines (not shown) and power lines (not shown), each of the data lines is electrically connected to first ends of first transistors of corresponding pixel driving circuits, and each of the scan line is electrically connected to control terminals of the first transistors of the corresponding pixel driving circuits, each of the power lines is electrically connected to first terminals of the second transistors of the corresponding pixel driving circuits; each of the light-emitting elements 120 is electrically connected to the second end of the second transistor of a corresponding pixel driving circuit; each of the bonding pad 130 is electrically connected to a data line and a scan line or a power line; but the present invention is not limited to thereto.

Please refer to FIG. 1B and FIG. 2B. Next, a protective layer 140 is formed on the outer lead bonding area 110b of each of the display units U. The protective layer 140 includes at least one protective pattern 142. The outer lead bonding area 110b of each of the display units U is covered by the protection pattern 142. The display area 110a and the connection area 110c of each of the display units U are offset from the protective pattern 142 and are not covered by the protective layer 140. In one embodiment, the display area 110a, the connection area 110c and the outer lead bonding area 110b of each of the display units U are arranged in the first direction d1, the first direction d1 intersects with the second direction d2, and the protection pattern 142 may be a strip pattern extending in the second direction d2 and covering of bonding pads 130, but the invention is not limited thereto. In one embodiment, the protective pattern 142 may include polyimide (PI) or peelable glue, but the invention is not limited thereto. In one embodiment, the protective layer 140 can be formed by spraying or screen printing, but the invention is not limited thereto.

Please refer to FIG. 1C and FIG. 2C. Next, an encapsulation glue layer 150 is formed on each of the display units U to cover the light-emitting elements 120 and the protective layer 140. In one embodiment, the protective pattern 142 of the protective layer 140 has end portions 142e extending outside the encapsulation glue layer 150 (marked in FIG. 2C). In one embodiment, the encapsulation glue layer 150 is light-transmissive, and the light-transmissive encapsulation glue layer 150 covers top surfaces 120a and side surfaces 120b of the light-emitting elements 120. However, the present invention is not limited thereto. In other not-shown embodiments, the encapsulation glue layer 150 may be light-absorbing, and the light-absorbing encapsulation glue layer 150 may cover the side surfaces 120b of the light-emitting elements 120 but expose the top surfaces 120a of the light-emitting elements 120. Referring to FIG. 1C, there is a height difference between the stacked structure S of the bonding pad 130 and the protection pattern 142 and the circuit substrate 110 to form an undulating topography. Affected by the undulating topography, the encapsulation glue layer 150 forms thick portions 154a′ and 154b′ next to the stacked structure S.

Please refer to FIG. 1C, FIG. 1D, FIG. 2C and FIG. 2D. Next, the protective layer 140 and a portion of the encapsulation glue layer 150 on the protective layer 140 are removed to expose the bonding pads 130. Specifically, in one embodiment, one end portion 142e of the protection pattern 142 can be pulled up first, and then the protection pattern 142 and the portion of the encapsulation glue layer 150 thereon are removed from the outer lead bonding area 110b of the display unit U along the second direction d2. After removing the protective pattern 142 and the portion of the encapsulation glue layer 150 thereon, the thick portions 154a′ and 154b′ originally located next to the stacked structure S will form thick wall portions 154a and 154b. Please refer to FIG. 1C. For example, in one embodiment, the thickness T140 of the protective layer 140 is 100 μm. When the protective layer 140 is removed, the thickness t150 of the portion of the encapsulation glue layer 150 on the protective layer 140 that can be removed together may be fall within the range of 15 μm ˜100 μm, but the present invention is not limited to thereto.

Please refer to FIG. 1C and FIG. 1D, the width W154a of the thick wall portion 154a in the first direction d1 is related to the thickness T140 of the protective layer 140. When the thickness T140 of the protective layer 140 is larger, the width W154a of the thick wall portion 154a is wider. For example, in several embodiments, the corresponding numerical values of the thickness T140 of the protective layer 140 and the width W154a of the thick wall portion 154a are as shown in Table 1 below, but the invention is not limited thereto.

TABLE 1

| the thickness T140 of the | the width W154a of the thick |
|---|---|
| protective layer 140(μm) | wall portion 154a (μm) |
| 20 | 571 |
| 50 | 753 |
| 100 | 984 |
| 150 | 1152 |
| 200 | 1372 |

Please refer to FIG. 1E. Next, the driving circuit board 160 is electrically connected to the bonding pads 130, a protective glue 170 is formed on the outer lead bonding area 110b to at least cover the connection between the driving circuit board 160 and the bonding pads 130, and an optical film 180 is formed on the encapsulation layer 150. Next, the display panel DP and the outer frame 190 are assembled, and the display apparatus 10 is completed, wherein the display panel DP includes a circuit substrate 110, light-emitting elements 120, the bonding pads 130, the encapsulation glue layer 150, the driving circuit board 160, the protective glue 170 and the optical film 180.

Please refer to FIG. 1D and FIG. 1E. In one embodiment, one thick wall portions 154b may be selectively removed before bonding the driving circuit board 160 to the bonding pad 130, but the invention is not limited thereto. In one embodiment, the driving circuit board 160 may be a flexible printed circuit board (FPC) or a chip on film package (COF), but the invention is not limited thereto.

Please refer to FIG. 1C, FIG. 1D and FIG. 1E. It is worth mentioning that the outer lead bonding area 110b of the circuit substrate 110 is covered with a patterned protective layer 140 and then the encapsulation glue layer 150 is formed; then, after the protective layer 140 is removed, the encapsulation glue layer 150 covering the light-emitting elements 120 but not the bonding pads 130 is left, which is helpful for the subsequent bonding of the driving circuit board 160 and the bonding pads 130.

Referring to FIG. 1E, the display apparatus 10 includes a circuit substrate 110, light-emitting elements 120, a bonding pad 130 and an encapsulation glue layer 150. The circuit substrate 110 has a display area 110a, an outer lead bonding area 110b, and a connection area 110c connected between the display area 110a and the outer lead bonding area 110b. The light-emitting elements 120 are disposed on the display area 110a of the circuit substrate 110. The bonding pad 130 is disposed on the outer lead bonding area 110b of the circuit substrate 110. The encapsulation glue layer 150 is disposed on the circuit substrate 110 and includes a flat portion 152 and a thick wall portion 154a connected to each other, wherein the flat portion 152 covers the light-emitting elements 120, the thick wall portion 154a extends to the connection area 110c, and the thick wall portion 154a has a thickness T154a that gradually increases toward the outer lead bonding area 110b.

In one embodiment, the display apparatus 10 further includes an optical film 180 disposed on the flat portion 152 of the encapsulation glue layer 150 and covering the light-emitting elements 120, wherein the thick wall portion 154a of the encapsulation glue layer 150 protrudes from the optical film 180 in a first direction d1 parallel to the circuit substrate 110. In one embodiment, the thick wall portion 154a of the encapsulation glue layer 150 may protrude from the optical film 180 in a third direction d3 perpendicular to the circuit substrate 110. However, the present invention is not limited thereto. In other embodiments, the thick wall portion 154a of the encapsulation glue layer 150 may not protrude from the optical film 180 in the third direction d3 perpendicular to the circuit substrate 110.

In one embodiment, the thick wall portion 154a of the encapsulation glue layer 150 has a first end 154a-1 and a second end 154a-2 opposite to each other, the first end 154a-1 of the thick wall portion 154a is connected to the flat portion 152, the third end 154a-1 of the thick wall portion 154a is connected to the flat portion 152, the thickness T154a-1 of the first end 154a-1 of the thick wall portion 154a is greater than or equal to the thickness T152 of the flat portion 152 of the encapsulation glue layer 150, the second end 154a-2 of the thick wall portion 154a is located between the first end 154a-1 of the thick wall portion 154a and the outer lead bonding area 110b, the thickness T154a-2 of the second end 154a-2 of the thick wall portion 154a is greater than the thickness T154a-1 of the first end 154a-1 of the thick wall portion 154a. In one embodiment, the difference between the thickness T154a-2 of the second end 154a-2 of the thick wall portion 154a and the thickness T154a-1 of the first end 154a-1 of the thick wall portion 154a may be less than or equal to 100 μm; a horizontal distance D between the first end 154a-1 and the second end 154a-2 of the thick wall portion 154a is less than or equal to 1000 μm; but the invention is not limited thereto.

In one embodiment, the display apparatus 10 further includes an outer frame 190. The outer frame 190 defines the accommodation space R. The accommodation space R accommodates the bonding pad 130, the outer lead bonding area 110b of the circuit substrate 110, the connection area 110c of the circuit substrate 110, and the thick wall portion 154a of the encapsulation glue layer 150, and the light-emitting elements 120 are located outside the accommodation space R.

In one embodiment, the display apparatus 10 further includes a driving circuit board 160 and a protective glue 170. The driving circuit board 160 is electrically connected to the bonding pad 130. The thick wall portion side surface 154as of the thick wall portion 154a of the encapsulation glue layer 150 faces the bonding pad 130. The protective glue 170 covers the connection between the driving circuit board 160 and the bonding pad 130 and extends to the thick wall portion side surface 154as of the thick wall portion 154 of the encapsulation glue layer 150. In one embodiment, the height H of the thick wall portion side surface 154as is greater than the thickness T170 of the protective glue 170. The thick wall portion 154a of the encapsulation glue layer 150 may be used as a retaining wall to prevent the protective glue 170 from leaking to the flat portion 152 of the encapsulation glue 150 when it is not completely cured. For example, in one embodiment, the thickness T152 of the flat portion 152 of the encapsulation glue layer 150 is about 5 μm to 30 μm, the thickness T170 of the protective glue 170 is about 10 μm to 30 μm, and the height H of the thick wall portion side surface 154as of the encapsulation glue layer 150 may be slightly smaller or equal to 100 μm, but the present invention is not limited to thereto.

In one embodiment, the encapsulation glue layer 150 has an encapsulation glue layer side surface 152s and a thick wall portion side surface 154as connected to each other, the circuit substrate 110 has a circuit substrate side surface 110s1 and an outer lead bonding area side surface 110s2 connected to each other, and the thick wall portion side surface 154as of the encapsulation glue layer 150 faces the bonding pad 130, the outer lead bonding area side surface 110s2 of the circuit substrate 110 is far away from the display area 110a of the circuit substrate 110 and is a boundary of the outer lead bonding area 110b of the circuit substrate 110, the encapsulation glue layer side surface 152s of the encapsulation glue layer 150 and the circuit substrate side surface 110s1 of the circuit substrate 110 is substantially aligned, and a horizontal distance K between the thick wall portion side surface 154as of the encapsulation glue layer 150 and the outer lead bonding area side surface 110s2 of the circuit substrate 110 is greater than 0.

In one embodiment, the display apparatus 10 further includes an optical film 180, which is disposed on the flat portion 152 of the encapsulation glue layer 150 and covers the light-emitting elements 120, wherein the optical film 180 has an optical film side surface 180s1 and an edge side surface 180s2 connected to each other. The optical film side surface 180s1 of the optical film 180 and the encapsulation glue layer side surface 152s of the encapsulation glue layer 150 are substantially aligned with the circuit substrate side surface 110s1 of the circuit substrate 110, and the thick wall portion side surface 154as of the encapsulation glue layer 150 is located between the edge side surface 180s2 of the optical film 180 and the outer lead bonding area side surface 110s2 of the circuit substrate 110.

It must be noted here that the following embodiments follow the component numbers and part of the content of the previous embodiments, wherein the same numbers are used to represent the same or similar elements, and descriptions of the same technical content are omitted. For descriptions of omitted parts, please refer to the foregoing embodiments and will not be repeated in the following embodiments.

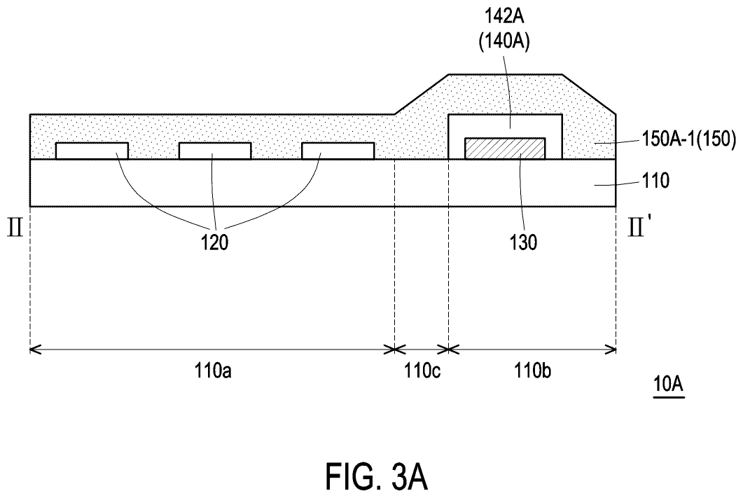

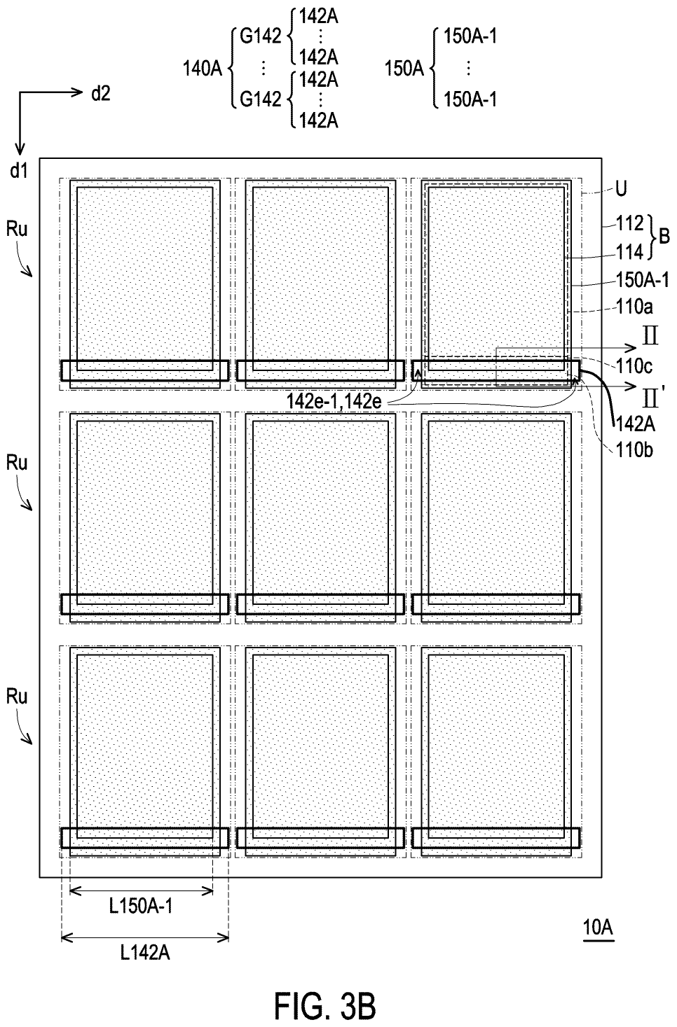

FIG. 3A is a schematic cross-sectional view of an array substrate according to an embodiment of the invention. FIG. 3B is a schematic top view of an array substrate according to an embodiment of the present invention. FIG. 3A corresponds to the section line II-II′ of FIG. 3B. FIG. 3A omits the light-emitting elements 120 and the bonding pad 130 of FIG. 3B.

The array substrate 10A of FIG. 3A and FIG. 3B is similar to the unfinished display apparatus of FIG. 1C and FIG. 2C. The main difference between the two is that the array substrate 10A of FIG. 3A and FIG. 3B has multiple display units U, and the protective layer 140A of FIG. 3A and FIG. 3B has multiple protective patterns 142.

Referring to FIG. 3A and FIG. 3B, the array substrate 10A includes display units U arranged in an array. Each of the display units U includes a block B of the circuit substrate 110, light-emitting elements 120 and bonding pads 130. The Block B of the circuit board 110 has a display area 110a, an outer lead bonding area 110b, and a connection area 110c connected between the display area 110a and the outer lead bonding area 110b. The light-emitting elements 120 are disposed on the display area 110a of the block B of the circuit substrate 110. The bonding pads 130 are disposed on the outer lead bonding area 110b of the block B of the circuit substrate 110.

In one embodiment, the array substrate 10A further includes a protective layer 140A, covering outer lead bonding areas 110b of the display units U, and staggered from display areas 110a and connection areas 110c of the display units U.

Please refer to FIG. 3B. Specifically, in one embodiment, the display area 110a, the connection area 110c and the outer lead bonding area 110b of each of the display units U are arranged in the first direction d1, and the display units U are arranged into display unit rows Ru, display units U of each of the display unit rows Ru are arranged in the second direction d2, the first direction d1 intersects with the second direction d2, the protective layer 140A includes protection pattern groups G142, each of the protection pattern groups G142 covers outer lead bonding areas 110b of display units U of a corresponding display unit row Ru along the second direction d2. For example, in one embodiment, each of the display unit rows Ru includes three display units U arranged in the second direction d2, and a protection pattern group G142 includes three protection patterns 142A arranged in the second direction d2, and these three protection patterns 142A respectively cover three outer lead bonding areas 110b of the three display units U of the same display unit row Ru, but the invention is not limited to thereto.

Please refer to FIG. 3A and FIG. 3B. In one embodiment, each of protection pattern groups G142 includes at least one protection pattern 142A. The array substrate 10A further includes an encapsulation glue layer 150A. The encapsulation glue layer 150A covers the protective layer 140A, display areas 110a and connection areas 110c of the display units U and bonding pads 130 of the of display units U, wherein at least one protection pattern 142A of each of the protection pattern groups G142 has end portions 142e extending outside the encapsulation glue layer 150A.

For example, in one embodiment, at least one protection pattern 142A of each of the protection pattern group G142 includes protection patterns 142A separated from each other, the protection patterns 142A are arranged in the second direction d2, each of the protection patterns 142A covers the outer lead bonding area 110b of the display unit U of the corresponding display unit row Ru and has sub-end portions 142e-1 respectively located on opposite sides of the display unit U, end portions 142e of at least one protection pattern 142A of each of protection pattern group G142s extending outside the encapsulation glue layer 150A are the sub-end portions 142e-1 of the protection patterns 142A.

In one embodiment, the encapsulation glue layer 150A may include encapsulation patterns 150A-1 separated from each other. The encapsulation patterns 150A-1 respectively cover display units U of the corresponding display unit rows Ru and respectively cover protection patterns 142A. In one embodiment, the length L142A (marked in FIG. 3B) of the protection pattern 142A in the second direction d2 is greater than the length L150A-1 (marked in FIG. 3B) of the corresponding encapsulation pattern 150A-1 in the second direction d2.

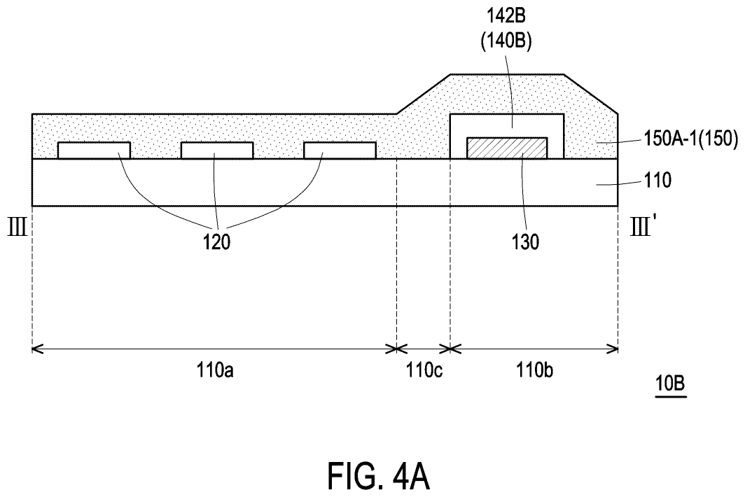

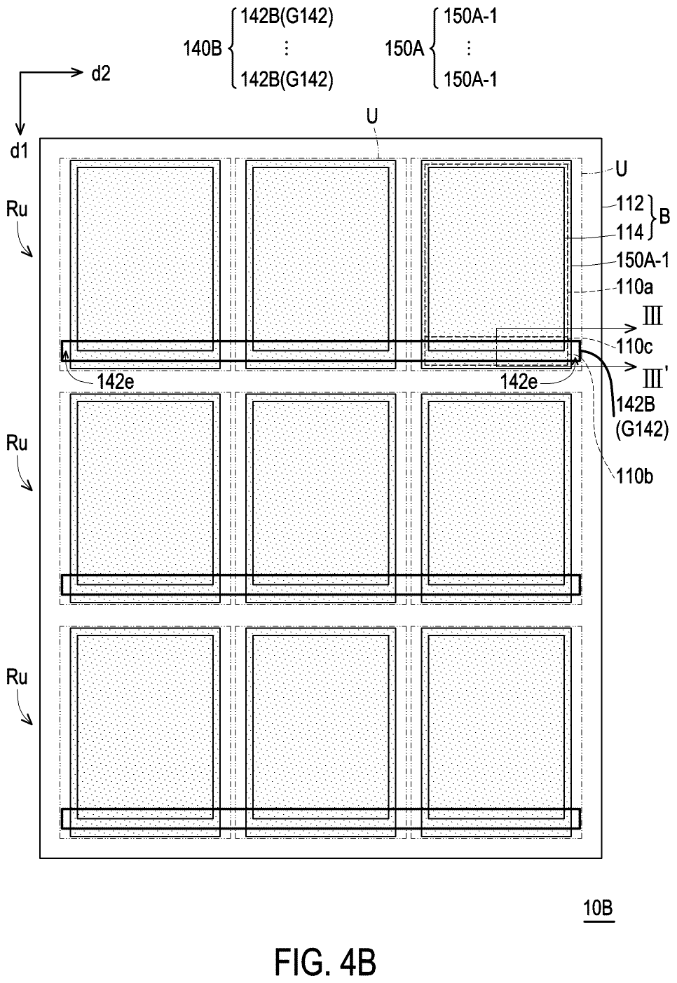

FIG. 4A is a schematic cross-sectional view of an array substrate according to another embodiment of the present invention. FIG. 4B is a schematic top view of an array substrate according to another embodiment of the present invention. FIG. 4A corresponds to the section line III-III′ of FIG. 4B. FIG. 4A omits the light-emitting element 120 and the bonding pad 130 of FIG. 4B.

The array substrate 10B of FIG. 4A and FIG. 4B is similar to the array substrate 10A of FIG. 3A and FIG. 3B. The main difference between the two is that the protective layer 140B of FIG. 4A and FIG. 4B is different from the protective layer 140A of FIG. 3A and FIG. 3B. Specifically, in the embodiment of FIG. 4A and FIG. 4B, each of the protection pattern groups G142 includes a protection pattern 142B. The protection pattern 142B extends continuously in the second direction d2 and has end portions 142e located on opposite sides of the corresponding display unit row Ru.

In the embodiment of FIG. 4A and FIG. 4B, the encapsulation glue layer 150A includes encapsulation patterns 150A-1 separated from each other. The encapsulation patterns 150A-1 respectively cover display units U of a corresponding display unit row Ru and cover a protection pattern 142B of a protection pattern group G142.

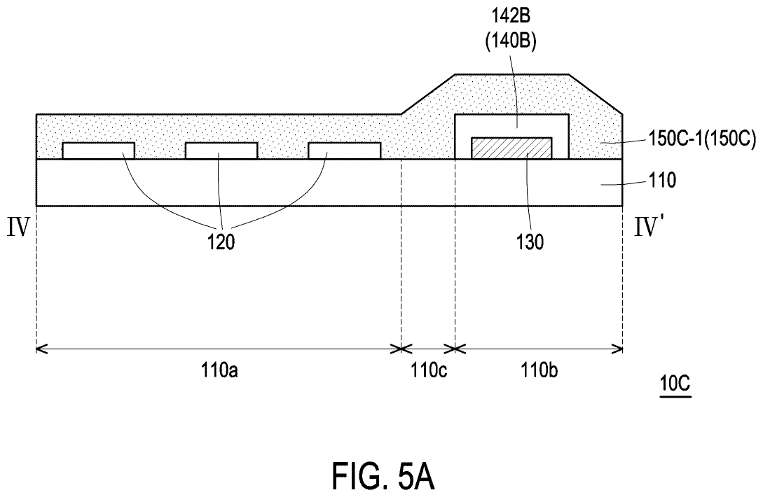

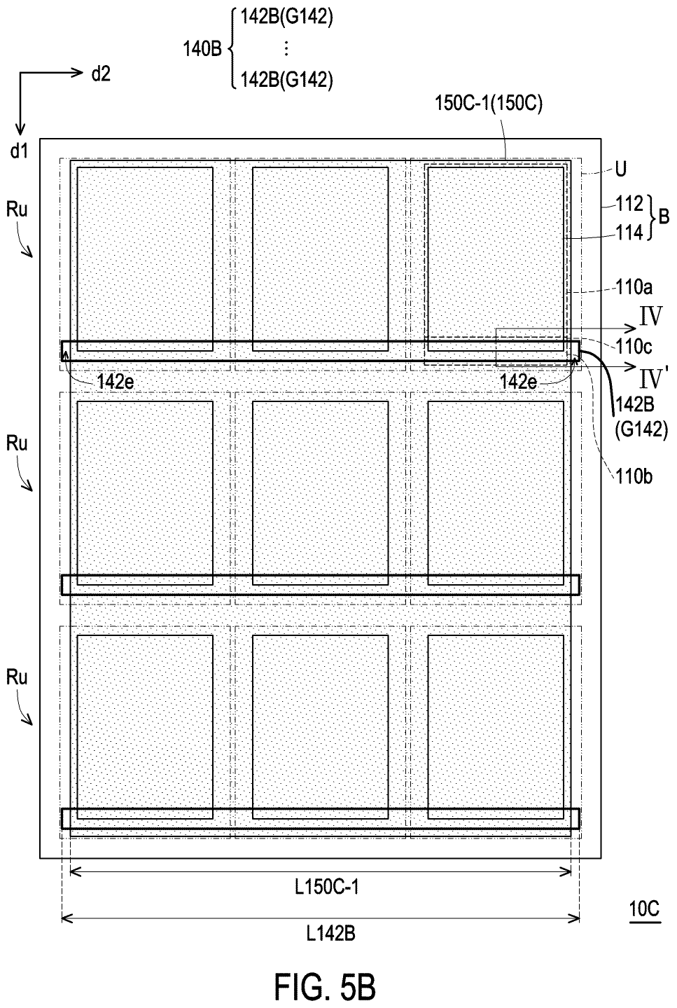

FIG. 5A is a schematic cross-sectional view of an array substrate according to yet another embodiment of the present invention. FIG. 5B is a schematic top view of an array substrate according to yet another embodiment of the present invention. FIG. 5A corresponds to the cross-section line IV-IV′ of FIG. 5B. FIG. 5A omits the light-emitting element 120 and the bonding pad 130 of FIG. 5B.

The array substrate 10C of FIG. 5A and FIG. 5B is similar to the array substrate 10B of FIG. 4A and FIG. 4B. The main difference between the two is that the encapsulation glue layer 150C in FIG. 5A and FIG. 5B is different from the encapsulation glue layer 150A in FIG. 4A and FIG. 4B. Specifically, in the embodiment of FIG. 5A and FIG. 5B, the encapsulation glue layer 150C includes an encapsulation pattern 150C-1. The encapsulation pattern 150C-1 continuously extends in the second direction d2 and covers display units U of corresponding at least one display unit row Ru and at least one protection pattern 142B. For example, in one embodiment, the encapsulation pattern 150C-1 covers display units U of three display unit rows Ru and three protection patterns 142B, but the invention is not limited thereto. In one embodiment, the length L142B (marked in FIG. 4B) of the protection pattern 142B in the second direction d2 is greater than the length L150C-1 (marked in FIG. 4B) of the encapsulation pattern 150C-1 in the second direction d2.

It will be apparent to those skilled in the art that various modifications and variations can be made to the disclosed embodiments without departing from the scope or spirit of the disclosure.

In view of the foregoing, it is intended that the disclosure covers modifications and variations provided that they fall within the scope of the following claims and their equivalents.

What is claimed is:

1. A display apparatus comprising:
a circuit substrate having a display area, an outer lead bonding area, and a connection area connected between the display area and the outer lead bonding area;
a plurality of light-emitting elements disposed in the display area of the circuit substrate;
a bonding pad disposed on the outer lead bonding area of the circuit substrate; and
an encapsulation glue layer disposed on the circuit substrate and comprising a flat portion and a thick wall portion connected to each other, wherein the flat portion covers the light-emitting elements, the thick wall portion extends to the connection area, and the thick wall portion has a thickness that increases toward the outer lead bonding area.

2. The display apparatus according to claim 1, further comprising:
an optical film, disposed on the flat portion of the encapsulation glue layer and covers the plurality of light-emitting elements, wherein the thick wall portion of the encapsulation glue layer protrudes from the optical film.

3. The display apparatus according to claim 1, wherein the thick wall portion has a first end and a second end opposite to each other, the first end of the thick wall portion is connected to the flat portion, the second end of the thick wall portion is located between the first end of the thick wall portion and the outer lead bonding area, an thickness of the second end of the thick wall portion is greater than an thickness of the first end of the thick wall portion, and a difference between the thickness of the second end of the thick wall portion and the thickness of the first end of the thick wall portion is less than or equal to 100 μm.

4. The display apparatus according to claim 1, wherein the thick wall portion has a first end and a second end opposite to each other, the first end of the thick wall portion is connected to the flat portion, the second end of the thick wall portion is located between the first end of the thick wall portion and the outer lead bonding area, and a horizontal distance between the first end of the thick wall portion and the second end of the thick wall portion is less than or equal to 1000 μm.

5. The display apparatus according to claim 1, further comprising:
an outer frame, wherein the outer frame defines an accommodation space, the accommodation space accommodates the bonding pad, the outer lead bonding area of the circuit substrate, the connection area of the circuit substrate, and the thick wall portion of the encapsulation glue layer, and the plurality of light-emitting elements are located outside the accommodation space.

6. The display apparatus according to claim 1, further comprising:
a driving circuit board and a protective glue, wherein the driving circuit board is electrically connected to the bonding pad, a thick wall portion side surface of the thick wall portion of the encapsulation glue layer faces the bonding pad, the protective glue covers a connection between the driving circuit board and the bonding pad and extends to the thick wall portion side surface of the thick wall portion of the encapsulation glue layer.

7. The display apparatus according to claim 6, wherein a height of the thick wall portion side surface of the thick wall portion is greater than a thickness of the protective glue.

8. The display apparatus according to claim 1, wherein the encapsulation glue layer has an encapsulation glue layer side surface and a thick wall portion side surface connected to each other, the circuit substrate has a circuit substrate side surface and an outer lead bonding area side surface connected to each other, the thick wall portion side surface of the encapsulation glue layer faces the bonding pad, the outer lead bonding area side surface of the circuit substrate is far away from the display area of the circuit substrate and is a boundary of the outer lead bonding area of the circuit substrate, the encapsulation glue layer side surface of the encapsulation glue layer is substantially aligned with the circuit substrate side surface of the circuit substrate, and a horizontal distance between the thick wall portion side surface of the encapsulation glue layer and the outer lead bonding area side surface of the circuit substrate is greater than 0.

9. The display apparatus according to claim 8, further comprising:
an optical film, disposed on a flat portion of the encapsulation glue layer and covers the plurality of light-emitting elements, wherein the optical film has an optical film side surface and an edge side surface connected to each other, an optical film side surface of the optical film, the encapsulation glue layer side surface of the encapsulation glue layer and the circuit substrate side surface of the circuit substrate are substantially aligned, and the thick wall portion side surface of the encapsulation glue layer is located between the edge side surface of the optical film and the outer lead bonding area side surface of the circuit substrate.

10. An array substrate comprising:
a plurality of display units arranged in an array, wherein each of the plurality of display units comprising:
a block of a circuit substrate having a display area, an outer lead bonding area, and a connection area connected between the display area and the outer lead bonding area;
a plurality of light-emitting elements disposed on the display area; and
a bonding pad disposed on the outer lead bonding area.

11. The array substrate according to claim 10, further comprising:
a protective layer covering outer lead bonding areas of the plurality of display units and staggered with display areas and connection areas of the plurality of display units.

12. The array substrate according to claim 11, wherein the display area, the connection area and the outer lead bonding area of each of the plurality of display units are arranged in a first direction, the display units are arranged in display unit rows, and display units of each of the display unit rows are arranged in a second direction, the first direction and the second direction are staggered, the protective layer comprises protection pattern groups, and each of the protection pattern groups covers outer lead bonding areas of display units of a corresponding display unit row along the second direction.

13. The array substrate according to claim 12, wherein the each of the protection pattern groups comprises at least one protection pattern, the array substrate further comprising:
an encapsulation glue layer covering the protective layer, the display areas of the plurality of display units, the connection areas of the plurality of display units, and bonding pads of the plurality of display units;
wherein the at least one protection pattern of the each of the protection pattern groups has end portions extending outside the encapsulation glue layer.

14. The array substrate according to claim 13, wherein the each of the protection pattern groups comprises a protection pattern extending continuously in the second direction and has end portions located on opposite sides of the corresponding display unit row.

15. The array substrate according to claim 14, wherein the encapsulation glue layer comprises encapsulation patterns separated from each other, and the encapsulation patterns respectively cover the plurality of display units of the corresponding display unit row and cover the protection pattern.

16. The array substrate according to claim 14, wherein the encapsulation glue layer comprises an encapsulation pattern, the encapsulation pattern continuously extends in the second direction and covers the plurality of display units of the corresponding display unit row and the protection pattern.

17. The array substrate according to claim 16, wherein a length of the protection pattern in the second direction is greater than the length of the encapsulation pattern in the second direction.

18. The array substrate according to claim 13, wherein the at least one protection pattern of the each of the protection pattern groups comprises protection patterns separated from each other, the protection patterns are arranged in the second direction, each of the protection patterns covers the outer lead bonding area of a display unit of the corresponding display unit row and has sub end portions respectively located on opposite sides of the plurality of display unit, and the end portions of the at least one protection pattern of the each of protection pattern groups extending outside the encapsulation glue layer comprises the sub end portions.

19. The array substrate according to claim 18, wherein the encapsulation glue layer comprises encapsulation patterns separated from each other, and the encapsulation patterns respectively cover the plurality of display units of the corresponding display unit row and respectively cover the protection patterns.

20. The array substrate according to claim 19, wherein a length of the at least one protection pattern in the second direction is greater than a length of a corresponding encapsulation pattern of the encapsulation patterns in the second direction.
